(19) United States
(12) Patent Application Publication
(10) Pub. No.: US 2025/0343527 A1
(43) Pub. Date: Nov. 6, 2025

(54) SURFACE ACOUSTIC WAVE DEVICE INCORPORATING A THIN LAYER OF METAL MATERIAL

(71) Applicant: Soitec, BERNIN (FR)

(72) Inventors: Sylvain Ballandras, BERNIN (FR); Thierry Laroche, BERNIN (FR); Alexandre Clairet, BERNIN (FR); Eric Michoulier, BERNIN (FR)

(21) Appl. No.: 18/866,728

(22) PCT Filed: Mar. 21, 2023
(86) PCT No.: PCT/EP2023/057115

§ 371 Date: Nov. 18, 2024

(30) Foreign Application Priority Data
May 18, 2022 (FR) FR2204700

(51) Int. Cl. H03H 9/02; H03H 3/08; H03H 9/145; H03H 9/25

(52) U.S. Cl. CPC H03H 9/02913; H03H 3/08; H03H 9/02559; H03H 9/145; H03H 9/25

(57) ABSTRACT

A surface wave device comprises a substrate; a piezoelectric layer above an upper face of the substrate; a pair of electrodes in contact with the piezoelectric layer, the two electrodes including fingers extending in the same direction so as to form a periodic structure in which the fingers of the two electrodes alternate with each other, and having an interdigital distance separating the centers of two adjacent fingers of the same electrode; a metal layer interposed between the substrate and the piezoelectric layer; and a dielectric layer interposed between the metal layer and the piezoelectric layer, wherein the metal layer has a thickness of 5 nm to 100 nm and the dielectric layer has a thickness of 25 nm to 600 nm.

### CROSS-REFERENCE TO RELATED APPLICATIONS

This application is a national phase entry under 35 U.S.C. § 371 of International Patent Application PCT/EP2023/057115, filed Mar. 21, 2023, designating the United States of America and published as International Patent Publication WO 2023/222282 A1 on Nov. 23, 2023, which claims the benefit under Article 8 of the Patent Cooperation Treaty of French Patent Application Serial No. FR2204700, filed May 18, 2022.

### TECHNICAL FIELD

The present disclosure is that of surface acoustic wave (SAW) devices with composite structures incorporating a thin layer of piezoelectric material resting on a semiconductor substrate.

### BACKGROUND

Surface acoustic wave devices, or SAW devices, are used in a wide range of applications, particularly in electronics, where they form the core element of filters, oscillators, delay lines and transformers.

Piezoelectric materials generate an electrical voltage when deformed by mechanical stress, and conversely deform when an electrical voltage is applied.

As a result, when an alternating electrical signal is applied to one or more electrodes in contact with the piezoelectric material, a corresponding mechanical signal (that is, oscillation or vibration) is generated at the piezoelectric material: the electrical signal is translated into a mechanical signal.

The mechanical signal translated into the piezoelectric material exhibits a frequency dependence on the alternating electrical signal, which is based on the characteristics of the electrode(s), the properties of the piezoelectric material and other factors such as the shape of the acoustic wave device and other structures making up the device.

Surface wave devices exploit this frequency dependence to provide one or more functions by way of surface acoustic wave (SAW) resonators or SAW transducers, which are increasingly used to form, for example, so-called “SAW filters” implemented in the transmission and reception of RF signals for telecommunication applications.

A SAW filter comprises at least one SAW transducer, potentially connected to other transducers so as to perform a filtering function between an input port and an output port.

A SAW filter typically comprises an input SAW transducer and an output SAW transducer formed on the same piezoelectric element, the input SAW transducer generating surface acoustic waves from an incoming electrical signal, the output SAW transducer receiving the surface acoustic wave and converting it into an outgoing electrical signal.

The geometry and dimensions of the transducers, and the types and shapes of the materials used, determine the characteristics of the SAW filter, such as coupling and reflection factors, Q quality factors at resonance or anti-resonance, bandwidth, parasitic responses, suppression of high-order resonances, and temperature dependence.

Patent U.S. Pat. No. 10,938,367 B2 discloses an interdigital SAW transducer (IDT) 100, shown in FIGS. 1A and 1B, with a top view in FIG. 1A and a sectional view along the XX′ plane in FIG. 1B.

The interdigital SAW transducer 100 comprises a piezoelectric layer 140 resting on a substrate 110, a pair of electrodes 150A and 150B in contact with a surface of the piezoelectric layer 140, a metal layer 120 interposed between the substrate 110 and the piezoelectric layer 140, and a dielectric layer 130 interposed between the metal layer 120 and the piezoelectric layer 140.

The electrodes 150A and 150B respectively comprise fingers 152A and 152B extending in the same direction D so as to form a periodic structure of period 2p in a direction perpendicular to direction D, wherein the fingers of the two electrodes are placed alternately, in a conventional manner.

The dielectric layer and the metal layer interposed between the piezoelectric layer and its substrate improve the transducer's behavior, and more particularly limit the appearance of parasitic responses, induced losses linked to the properties of the substrate and interface effects within the stack.

However, the information disclosed by U.S. Pat. No. 10,938,367 B2 remains insufficient for practical applications requiring special features and/or high performance levels for a SAW transducer.

### BRIEF SUMMARY

One aim of the present disclosure is to characterize surface wave devices in such a way as to provide them with sufficient operational parameters to implement them in practical applications, beyond the simple operating principles of the prior art.

To this end, the present disclosure relates to a surface acoustic wave device comprising a substrate; a piezoelectric layer above an upper face of the substrate; a pair of electrodes in contact with the piezoelectric layer, the two electrodes comprising fingers extending in the same direction so as to form a periodic structure in which the fingers of the two electrodes alternate with each other, and having an interdigital distance separating the centers of two adjacent fingers of the same electrode; a metal layer interposed between the substrate and the piezoelectric layer; and at least one dielectric layer interposed between the metal layer and the piezoelectric layer, wherein the metal layer has a thickness of between 5 nm and 100 nm and the dielectric layer(s) has (have) a thickness of between 25 nm and 600 nm.

Such a device represents the culmination of a compromise suitable for implementation as an acoustic wave device benefiting from the positive electromagnetic shielding effects of a metal layer interposed between the piezoelectric layer and the substrate thereof, while maintaining excellent performance in terms of phase velocity, reflection coefficient and electromechanical coupling coefficient ks² in the device structure.

According to other non-limiting features of the present disclosure, either individually or in any technically feasible combination:
the metal layer can have a thickness of between 0.25% and 5% of the interdigital distance;
the dielectric layer can have a thickness of between 250 nm and 400 nm;
the dielectric layer can have a thickness greater than five times the thickness of the metal layer;
the dielectric layer can be less than 200 nm thick;
an optional dielectric layer can be interposed between the substrate and the metal layer;
the dielectric layer and the optional dielectric layer can each be less than 300 nm thick;
the sum of the dielectric layer thickness and the optional dielectric layer thickness is less than 200 nm;
the ratio of the optional dielectric layer thickness to the sum of the dielectric layer thickness and the optional dielectric layer thickness can be between 15% and 30%;
the piezoelectric layer may comprise a juxtaposition of a lithium tantalate LiTaO₃ layer and a lithium niobate LiNbO₃ layer; and
the metal layer comprises metalized surfaces separated by a distance less than or equal to the interdigital distance.

The present disclosure extends to a filter device comprising the surface acoustic wave device.

The present disclosure also relates to a method for manufacturing the device, comprising a direct bonding step.

### BRIEF DESCRIPTION OF THE DRAWINGS

Other features and advantages of the present disclosure will emerge from the following detailed description of the present disclosure with reference to the appended figures, wherein:

FIGS. 1A and 1B schematically illustrate a known interdigital SAW transducer, in planar view and cross-section, respectively;

FIGS. 2A and 2B schematically illustrate an interdigital SAW transducer according to the present disclosure, in planar view and cross-section, respectively;

FIGS. 3A and 3B illustrate two graphs showing the effect of a metal layer in an interdigital SAW transducer;

FIGS. 4A-4D illustrate four graphs showing characteristic quantities of the transducer in FIGS. 2A and 2B as a function of the thickness of the metal layer 220;

FIGS. 5A-5D illustrate four graphs each showing the conductance and admittance of a structure similar to FIGS. 2A and 2B as a function of the facing metal surfaces;

FIGS. 6A-6F illustrate six graphs showing the harmonic admittance for different thicknesses of the dielectric layer of the transducer in FIGS. 2A and 2B;

FIGS. 7A-7D illustrate four graphs showing characteristic quantities of the transducer in FIGS. 2A and 2B as a function of the thickness of the dielectric layer 230;

FIG. 8 illustrates an alternative of the transducer structure of FIGS. 2A and 2B, with an optional dielectric layer 330;

FIG. 9 illustrates an acoustic wave device comprising two transducers corresponding to that of FIGS. 2A and 2B or FIG. 8;

FIGS. 10A-10F illustrate six graphs showing the harmonic admittance for different combinations of thicknesses of the dielectric layers 230 and 330 of the transducer of FIG. 8;

FIG. 11 shows a manufacturing method for the devices of FIGS. 2 and 8; and

FIG. 12 shows a discontinuous metal layer.

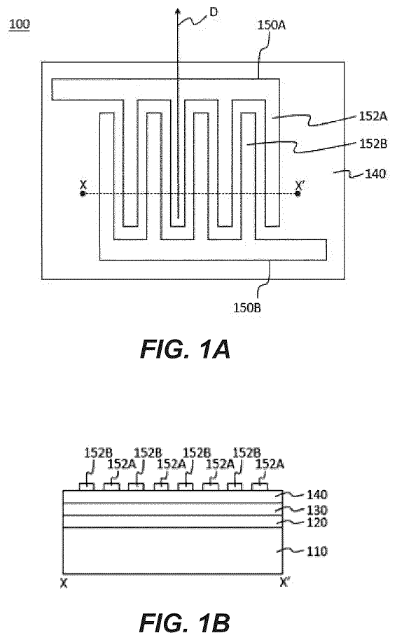

### DETAILED DESCRIPTION

The inventors of the present disclosure started with a generic interdigital SAW transducer structure, and carried out extensive digital modeling to determine certain parameters critically influencing the performance of an interdigital SAW transducer, and to define design rules for such a transducer.

### Structure 1—Single Dielectric Layer

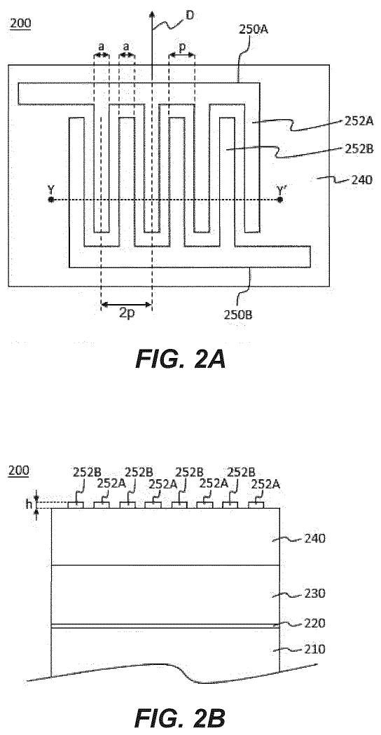

FIG. 2A is a planar view of an interdigital SAW transducer 200 according to the present disclosure, and FIG. 2B is a cross-section of this transducer in the plane passing through the segment YY′ and perpendicular to the planar view.

The interdigital SAW transducer 200 comprises a piezoelectric layer 240 resting on a substrate 210; a pair of electrodes comprising a first electrode 250A and a second electrode 250B each in contact with a surface of the piezoelectric layer 240 located on top thereof so that the piezoelectric layer 240 is interposed between the substrate 210 and the pair of electrodes; a metal layer 220 interposed between the substrate 210 and the piezoelectric layer 240; and a dielectric layer 230 interposed between the metal layer 220 and the piezoelectric layer 240.

In this example, the piezoelectric layer 240 is in direct contact with the dielectric layer 230, the dielectric layer 230 is in direct contact with the metal layer 220, and the metal layer 220 is in direct contact with the substrate 210.

The electrodes 250A and 250B respectively comprise fingers 252A and 252B extending in the same direction D, so as to form a periodic structure of period p in a direction perpendicular to direction D, wherein the fingers of the two electrodes are placed alternately, as seen, in particular, in FIG. 2B, so as to form a conventional interdigital structure.

The acoustic wavelength k of the operated mode is equal to the period 2p, and non-limitingly the transducer operates under Bragg conditions (the electrode period p of the transducer is half the wavelength λ) for this particular wavelength.

This period 2p is understood as the distance separating the central extension axes of two adjacent fingers of the same electrode, that is, axes each forming an axis of symmetry of the corresponding finger, this axis being parallel to the direction D of extension of the fingers.

The substrate 210 is preferably made of silicon, and even more preferably, of high acoustic quality silicon, but can also be made, for example, of glass or ceramic or another semiconductor material.

Preferably, the metal layer 220 and the electrodes 250A and 250B are independently made of a light metal considered to be a good electrical conductor, such as aluminum or an aluminum alloy such as Al—Cu, Al—Si or Al—Ti, in order to limit the mass loading effect and resistive losses on the transducer's frequency response.

However, due to its relatively low melting point, aluminum could lead to complications during transducer manufacture, particularly when heat treatments at a temperature above this melting point are applied, for example, to allow a LiTaO₃ piezoelectric layer to recover its piezoelectric properties.

In such a situation, metals heavier than aluminum can be used, despite their negative effects on the loading effect: molybdenum, tungsten, platinum or titanium, but also chromium, copper and nickel; alternatively, scandium and vanadium or even conductive carbon can be used, given their advantageous density.

It is understood that the metal layer 220 may be made of a different material from that constituting the electrodes 250A and 250B. Additionally, the metal layer can optionally be in contact with, for example, a fixed potential such as ground. This contact requires additional manufacturing steps, but makes the layer less sensitive to environmental RF signals.

The dielectric layer 230 consists of a dielectric material such as silica, preferably silicon dioxide SiO₂.

Other materials may also be considered, such as ZrO₂, Ta₂O₅, Si₃N₄ and combinations of these materials.

The gradual combination of SiO₂ and Si₃N₄ is also possible in the form of SiON for silicon oxy-nitride.

These dielectric materials can be in any crystalline form, e.g., polycrystalline or amorphous, as obtained using standard microelectronics deposition methods.

The piezoelectric layer 240 preferably consists of lithium tantalate LiTaO₃, lithium niobate LiNbO₃ or a juxtaposition of a layer of lithium tantalate LiTaO₃ and a layer of lithium niobate LiNbO₃; potassium niobate, gallium nitride, aluminum nitride, zinc oxide or quartz or any other piezoelectric material can also be used to form the piezoelectric layer 240.

The distance between two corresponding parts of a first finger 252A and a second finger 252B adjacent to this first finger defines an electrode period p of the interdigital SAW transducer 200.

The ratio between the width a of the fingers 252A and 252B and the electrode period p defines a metallization ratio M of the interdigital SAW transducer 200.

The electrode period p and the metallization ratio M together characterize the interdigital SAW transducer 200 and can determine, together with other factors such as the properties of the piezoelectric layer 240, the dielectric layer 230, the metal layer 220 or the substrate 210, the thickness h of the electrodes (or its relative form h/2p), the operational parameters of the SAW resonator.

During operation of the SAW resonator, an alternating electrical input signal supplied to the first electrode 250A is converted into a mechanical signal in the piezoelectric layer 240, generating one or more acoustic waves therein.

The resulting acoustic waves, translated from the electrical input signal, are mainly surface acoustic waves, which are sought in the operation of a SAW transducer.

The amplitude and phase of the acoustic waves thus generated in the piezoelectric layer depend on the frequency of the AC input signal, the electrode period p, the relative metal thickness h/2p and the metallization ratio M, as well as on the operating parameters of the interdigital SAW transducer 200.

This frequency dependence is often described in terms of changes in harmonic admittance, that is, harmonic conductance and harmonic susceptance, between the first electrode 250A and the second electrode 250B, varying with the frequency of the AC electrical input signal.

The acoustic waves translated from the input AC electrical signal travel through the piezoelectric layer 240 and finally reach the second electrode 250B, where they are converted into an output AC electrical signal.

The acoustic waves can also remain confined under the interdigital transducer when the latter is surrounded by reflective mirrors consisting of a network of electrodes similar to those of the transducer, preferentially, but not necessarily limited to, electrodes connected to electrical ground, with a mechanical period close or identical to that of the transducer and reflecting incident waves in phase toward the latter, thus creating a surface wave resonator. This resonator can form the basic element of a so-called “impedance element” filter, combining poles and zeros to form the desired transfer function.

Based on the generic structure disclosed above, numerous numerical models were carried out to determine the parameters to be set in order to be able to obtain interdigital SAW transducers meeting precise specifications, and, in particular, the thicknesses of the metal layer 220 and the dielectric layer 230.

Other parameters, such as phase velocity, reflection coefficient, dielectric permittivity or electromechanical coupling, follow an empirical law based on the thickness of the dielectric layer between the piezoelectric layer and the metal layer, according to equation 1 below:

$$f ( t ) = {a}_{0} + ( {a}_{1} + {a}_{2} t + {a}_{3} {t}^{2} ) \times ( ln ( {b}_{0} + {b}_{1} t + {b}_{2} {t}^{2} ) ) \\ f ( t ) = {a}_{0} + ( {a}_{1} + {a}_{2} t + {a}_{3} {t}^{2} ) \times ( ln ( {b}_{0} + {b}_{1} t + {b}_{2} {t}^{2} ) ) \qquad Eq . 1$$

The coefficients a₀ to a₃ and b₀ to b₂ depend on the operating frequency, the materials selected and the other thicknesses of this stack, apart from the thickness of the dielectric layer present between the piezoelectric layer and the metal layer.

Since the thicknesses of the metal layer 220 and the dielectric layer 230 are at least approximately determined, the skilled person will know how to choose and adjust the thicknesses and materials (including their respective orientations) in order to optimize the operation of the device based on its technical specifications.

### Model 1—Metal Layer, Interest

An initial series of models was used to verify the relevance of this generic structure, and, in particular, the advantages and potential drawbacks of the metal layer 220.

To this end, two structures equipped with interdigitated SAW electrodes were compared via modeling: on the one hand, a conventional structure with a piezoelectric/silicon oxide/silicon stack and, on the other, a structure similar to the conventional “metal layer structure,” but wherein a metal layer was introduced at the interface between silicon and silicon oxide, resulting in a piezoelectric/silicon oxide/metal/silicon stack.

This metal layer structure is shown in B) of FIG. 2, the conventional structure corresponding to the structure in FIG. 2 with the metal layer 220 omitted.

More specifically, the conventional structure consisted of a 600 nm-thick piezoelectric layer of LiTaO₃ (YXl)/42° according to IEEE Std-176 nomenclature, attached to a substrate consisting of a silicon wafer of orientation and residual conductivity of 100 S·^{m-1} via a 500 nm-thick layer of silicon oxide (modeled as fused quartz), corresponding respectively to layers 240, 210 and 230 of FIG. 2.

The electrodes were modeled as consisting of an infinite array of 2% copper aluminum alloy electrodes with an electrode period p of 1 μm, a metallization ratio M of 50% and a relative thickness h/λ (thickness normalized to the acoustic wavelength λ) of 5%.

The metal layer structure was identical to the conventional structure, except that it additionally comprised the metal layer 220 shown in FIG. 2, consisting of a 50% copper aluminum alloy 50 nm thick between the silicon substrate and the silicon oxide layer, a structure corresponding to the cross-sectional view in FIG. 2.

The harmonic admittances of these two structures were calculated using finite element and boundary element methods, more specifically, FEM-BIM (Finite Element Method-Boundary Integral Method).

Reference can be made to the publication of the calculation method by P. Ventura, J. M. Hode, M. Solal, J. Desbois, J. Ribbe “Numerical Method for SAW propagation characterization” in Proc. of the IEEE Ultrasonics Symposium, pp. 175-186, 1998, and its application to multi-layer materials by S. Ballandras, A. Reinhardt, V. Laude, A. Soufyane, S. Camou, W. Daniau, T. Pastureaud, W. Steichen, R. Lardat, M. Solal, P. Ventura, “Simulations of surface acoustic wave devices built on stratified media using a mixed finite element/boundary element integral formulation” in Journal of Applied Physics, vol. 96, No. 12, pp.7731-7741, 2004.

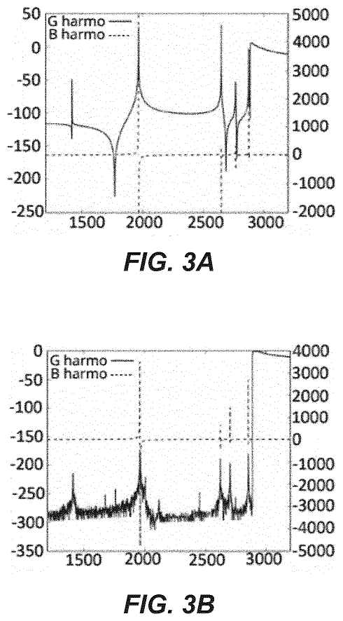

FIGS. 3A and 3B show the harmonic conductances and susceptances (respectively, Gₕₐᵣₘₒ in solid lines expressed in dB/S·^{m-1} on the ordinate axes on the left-hand side of each graph and Bₕₐᵣₘₒ susceptance in dotted lines expressed in S·^{m-1} on the ordinate axes on the right-hand side of each graph) of the conventional structure (in FIG. 3A) and the metal-layer structure (in FIG. 3B).

For the conventional structure, it appears that the conductance G is always greater than zero, and that the main and parasitic resonances have a finite G value, in contrast to the true (lossless) modes, for which G can be likened to a Dirac function.

The losses reflected by finite conductance (below −150 dB in FIGS. 3A and 3B) are solely due to parasitic conductance effects in the silicon substrate: the electric field associated with mechanical displacement penetrates the structure to a depth of more than 2λ (the typical value can reach 10) or more for pure shear waves) and therefore generates leakage currents that capture the excitation energy supplied by the input signal and convert it into heat.

Indeed, it can be demonstrated that the silicon substrate, even with high resistivity, has electric charge carriers with sufficiently long lifetimes to induce the creation of a parasitic capacitance at the interface between the silicon substrate 210 and the dielectric layer 230 of silicon oxide.

FIG. 3B shows that the introduction of the metal layer 220 between the silicon substrate 210 and the dielectric layer 230 of silicon oxide keeps the harmonic conductance values below the noise level, until the frequency reaches the so-called SSBW (Surface Skimming Bulk Wave) branching point, at which point the acoustic waves are no longer confined to the upper layers of the structure, but penetrate the volume of the silicon substrate in the form of radiated waves (the model assumes a silicon volume that is unlimited according to depth, see FIG. 2B).

The reason for the harmonic conductance attenuation is that the metal layer forms an electromagnetic shield between the piezoelectric layer and the substrate, eliminating any electric field penetration into the silicon substrate volume, thus suppressing the appearance of parasitic conductance.

This minimizes or even cancels out the mean free path of charges, thus significantly limiting or even prohibiting the existence of leakage currents due to coherent charge propagation at the interface.

The suppression of leakage by the metal layer is effective for any type of metal and any thickness of metal layer, but it is preferable to limit this thickness to avoid the appearance of new modes degrading the spectral purity of the structure confining the surface acoustic wave.

Additionally, using dense metals and increasing the thickness of the metal layer causes a mass loading effect of the layer, reducing acoustic wave propagation speeds and modifying the transducer's frequency response.

Thus, in order to limit the disadvantages mentioned in the two previous paragraphs, it is recommended to use for the metal layer (i) light metals, in particular, aluminum or an alloy with more than 90% aluminum such as Al—Cu, Al—Si or Al—Ti, and (ii) a metal thickness between 5 nm and 100 nm, or even between 5 nm and 10 nm.

It should be noted that other modeling studies have confirmed that the presence of a metal layer does not significantly modify the velocity of the mode and its ability to be reflected by the structure, and that its electromechanical coupling coefficient ks² is only slightly lower in the case of a metal layer than in the case of a structure without one.

It should also be noted that the metal layer 220 is not limited to a continuous layer, but can also consist of a pattern of separate metalized surfaces, which play the same shielding role as a continuous layer, but enable the mass loading effect to be limited.

In this context, the distance d separating two contiguous metalized surfaces should ideally be less than λ, preferably less than λ/2, more preferably, less than λ/4, as shown in FIG. 12, with a metal layer 220 consisting of a two-dimensional matrix of metalized surfaces 222 separated from one another by a distance d. This condition is by no means restrictive, but it does help to reduce the mean free path of charges induced at the oxide/silicon interface (and more generally, at the dielectric/semiconductor interface).

Non-limitingly, any kind of geometry and distribution (square, triangular, hexagonal, other) can be used for the elements of this matrix.

### Model 2—Metal Layer and Surface Waves

A second series of models was used to evaluate the effect of the thickness of the metal layer 220 on the characteristic quantities of surface waves and dielectric permittivity.

To this end, structures similar to the one shown in FIGS. 2A and 2B were considered, corresponding to the metal layer structure of the first series of models, except that this time the metal layer consists of a titanium layer with a thickness varying between 1 nm and 50 nm.

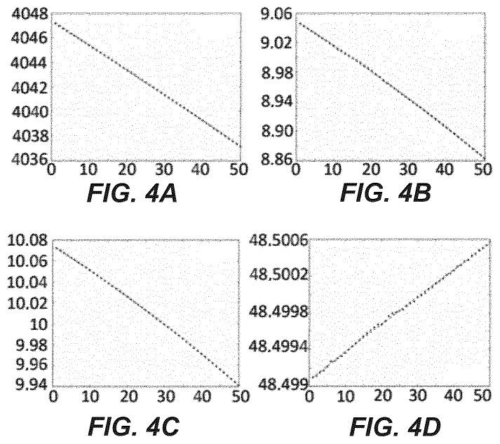

FIGS. 4A-4D show four graphs showing the evolution of characteristic surface-wave quantities and dielectric permittivity in such structures as a function of the thickness of the metal layer indicated on the abscissa, varying from 1 nm to 50 nm, with in FIG. 4A the phase velocity expressed in m·s⁻¹ and varying between 4036 and 4048, in FIG. 4B the reflection coefficient expressed as a percentage and varying between 8.86 and 9.06, in FIG. 4C the electromechanical coupling coefficient k²s expressed as a percentage and varying between 9.94 and 10.08, and in FIG. 4D the relative dielectric permittivity, dimensionless, varying between 48.499 and 48.5006.

These graphs show that increasing the thickness of the metal layer causes only a very slight degradation in the magnitudes that are characteristic of surface waves (phase velocity, reflection coefficient, electromechanical coupling coefficient).

Relative permeability is almost unaffected by this increase, with less than 1% variation, and variations in the reflection coefficient and electromechanical coupling coefficient remain of the order of 1%, so all these variations can be considered negligible.

For phase velocity, the mass loading effect of the metal layer is more significant, with a variation of around −2 m·s⁻¹·nm⁻¹ or −50 ppm·nm⁻¹.

It can be deduced from these findings that the thickness of the metal layer has an impact, and that it is advantageous to limit this impact by keeping the thickness of the metal layer below 100 nm, or even below 5%, more preferably, 2.5%, of the acoustic wavelength λ.

However, it is preferable to keep the thickness of the metal layer greater than 0.25% of the acoustic wavelength k in order to maintain the electromagnetic shielding effect provided by the metal layer.

### Model 3—Metal Layer and Parasitic Capacitance

In a third model series, using a model based on a Green's function (described in detail in A. Reinhardt, “Simulation, conception et réalisation de filtres à ondes de volume dans des couches minces piézoélectriques” [Simulation, design and realization of bulk-wave filters in piezoelectric thin films], Doctoral Thesis at the Universite de Franche-Comte in Engineering Sciences, 2005), the admittance was calculated, that is, conductance and susceptance, of a stack of materials comprising, from top to substrate, 100 nm aluminum, 600 nm LiTaO₃, 500 nm SiO₂ (modeled as fused quartz), 50 nm molybdenum, 650 μm silicon, and a semi-infinite polyimide support (kapton) to damp radiated waves from the surface to the core of the stack.

For the calculation, the quality factor Q for metal layers was set at 100, 1000 for SiO₂, and 10,000 for LiTO₃ and silicon. This quality factor is used to calculate the imaginary part of the acoustic constants Cᵢⱼ (non-conservative part of the problem) as Imaginary Part (Cij)=Real Part (Cij)/Q.

For the electrical aspect, the loss angle tg(δ) was set at 10⁻² for SiO₂, 10⁻³ for silicon and 10⁻⁴ for LiTaO₃. As before, this coefficient makes it possible to calculate the imaginary parts of the dielectric constants from their real values, according to the process well known to those skilled in the art.

The aluminum layer was configured so as to be representative of the metalization of a SAW filter in the frequency range from 1 to 2 GHz, that is, considered to occupy a surface area of no more than 1 mm².

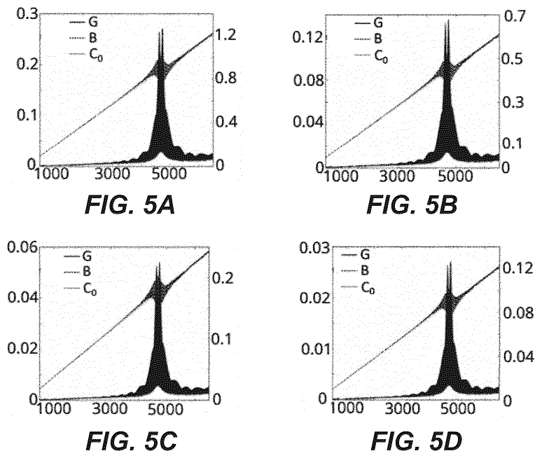

FIGS. 5A-5D are four graphs, each showing the conductance G, admittance B and static capacitance Co of a structure similar to that in FIGS. 2A and 2B, corresponding to aluminum surfaces of 500, 250, 100 and 50 μm², respectively.

In addition to demonstrating an HBAR (High Overtone Bulk Acoustic Resonator) effect above 3 GHz, the linearity of the effect on the conductance of the static capacitance Co formed by the opposing electrically conductive elements (metal layer 120 and electrodes 150A and 150B) and the dielectric layer 130 separating them was also considered.

Thus, to limit parasitic capacitance, the metalization of the piezoelectric layer should be limited, for example, by restricting the surface area occupied by the layer defining the resonator electrodes and their respective connection pads to values of less than 10⁴ μm².

Preferably, the cumulative surface area of the connection pads alone should remain below 10⁴ μm², each connection pad being defined as a region of the layer defining the electrodes forming a rectangle of sufficient surface area, designed to enable micro-welding by wedge bonding and ball bonding, respectively.

### Dielectric Layer

Initially, it should be noted that the presence of the dielectric layer 230 is necessary to reduce the HBAR (High Overtone Bulk Acoustic Resonator) effect due to the presence of the metal layer 220, and thereby reduce the parasitic responses thus induced in the interdigital SAW transducer 200.

### Model 4—Dielectric Layer and Admittance

Still in the metal-layer structure shown in FIGS. 2A and 2B, a fourth model series evaluated the effect of the thickness of the dielectric layer 230 interposed between the piezoelectric layer 240 and the metal layer 220 on the characteristics of the interdigital SAW transducer 200.

For this evaluation, structures similar to the one shown in FIGS. 2A and 2B were considered, corresponding to the metal-layer structure of the first series of models, except that the metal layer is made of molybdenum and the dielectric layer is made of a layer of silicon oxide SiO₂, the thickness of which was varied.

For the calculations, a quality factor Q of 10,000 was considered for the LiTaO₃ layer and silicon substrate, 1,000 for SiO₂, and 100 for molybdenum.

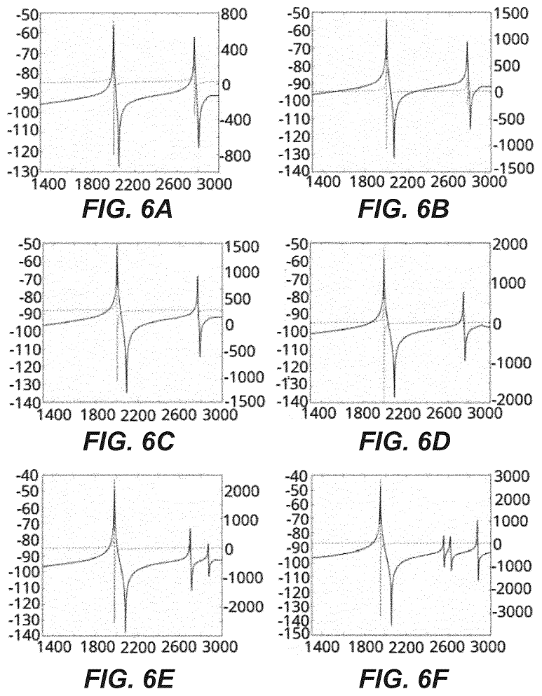

FIGS. 6A-6F are six graphs showing the evolution of the modulus and susceptance of the harmonic admittance as a function of the frequency indicated on the abscissa (harmonic modulus |Y|ₕₐᵣₘₒ in solid lines expressed in dB/S·μm⁻¹ on the ordinate axes on the left-hand side of each graph and susceptance Bₕₐᵣₘₒ in dotted lines expressed in S·m⁻¹ on the ordinate axes on the right-hand side of each graph), for SiO₂ thicknesses of 0, 20, 50, 100, 200 and 500 nm, respectively on the graphs of FIGS. 6A-6F.

It can be seen from these graphs that the distance between the resonance frequency (maximum harmonic conductance) and the anti-resonance frequency (minimum harmonic conductance) increases with SiO₂ thickness.

Both frequencies increase as the mass effect decreases, and the coupling between the metal layer and the piezoelectric layer decreases as the SiO₂ thickness increases.

It may therefore be advantageous to maximize the thickness of the SiO₂ layer.

It can also be seen that parasitic responses close to 2.7 GHz appear only for SiO₂ thicknesses greater than 200 nm, as can be seen in graphs of FIGS. 6E and 6F but not in the graphs of FIGS. 6A-6D.

Thus, it may be advantageous to use an oxide layer with a thickness of less than 200 nm, for example, between 50 m and 200 nm, preferably between 100 nm and 200 nm, to avoid the appearance of such parasitic responses.

### Model 5—Dielectric Layer and Surface Waves

A fifth series of models was used to evaluate the effect of the thickness of the dielectric layer 230 on the characteristic quantities of surface waves and dielectric permittivity.

For this evaluation, structures similar to that shown in FIGS. 2A and 2B were considered, corresponding to the metal layer structure of the first series of models, except that an aluminum alloy with 2% copper Al—Cu, titanium Ti, molybdenum Mo, copper Cu and nickel Ni were used for the metal layer, with the thickness of the dielectric layer varying between 0 and 400 nm.

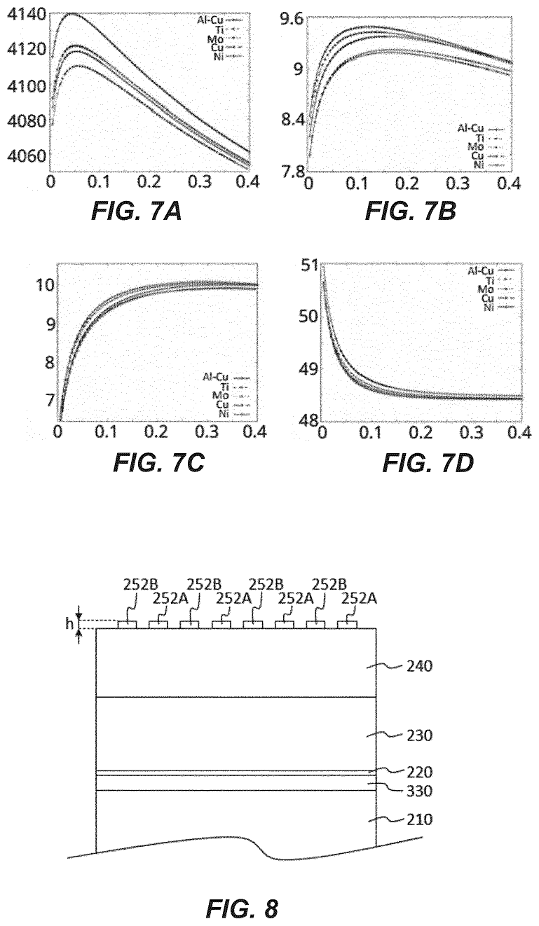

FIGS. 7A-7D are four graphs showing the evolution of characteristic surface-wave quantities and dielectric permittivity in such structures as a function of the thickness of the dielectric layer indicated on the abscissa, varying from 0 nm to 0.4 μm, with the phase velocity expressed in m·s⁻ and varying between 4050 and 4140 in FIG. 7A, the reflection coefficient expressed as a percentage and varying between 8 and 9.6 in FIG. 7B, the electromechanical coupling coefficient k²s expressed as a percentage and varying between 6.5 and 10 in FIG. 7C, and the relative dielectric permittivity, dimensionless, varying between 51 and 48.5 in FIG. 7D.

Each graph contains five curves, corresponding respectively to the nature of the metal layer under consideration (Al—Cu, Ti, Mo, Cu, Ni).

It can be seen from these graphs that the phase velocity, reflection coefficient and electromechanical coupling coefficient ks² each show a maximum for a SiO₂ thickness of less than 600 nm, and even less than 400 nm: around 50 nm for the phase velocity, between 80 nm and 180 nm for the reflection coefficient depending on the nature of the metal layer, and between 250 nm and 400 nm for the electromechanical coupling coefficient ks².

Thus, to strike a balance between the interest in maximizing SiO₂ thickness and that of maximizing one or more of the parameters mentioned in the previous paragraph, it is advantageous to choose a SiO₂ thickness of between 25 nm and 2 μm, preferably between 50 nm and 600 nm, more preferably, between 50 nm and 400 nm, even more preferably, between 250 nm and 400 nm.

Alternatively, preferential values for the SiO₂ thickness can be expressed in relative terms to the thickness of the metal layer, in which case a dielectric layer 230 thickness of between 0.5 and 40 times, preferably between 10 and 40 times, even more preferably, between 20 and 40 times the thickness of the metal layer 220, can advantageously be chosen.

The existence of maxima can also be exploited, for example, to maximize the electromechanical coupling ks² by choosing a SiO₂ thickness between 250 nm and 400 nm, to maximize the phase velocity by choosing a SiO₂ thickness between 25 nm and 100 nm, or to maximize the reflection coefficient by choosing a SiO₂ thickness between 80 nm and 180 nm.

### Structure 2—Double Dielectric Layer

An alternative to placing the metal layer 220 directly in contact with the substrate 210 is to interpose an optional dielectric layer 330 between them, to obtain the layered structure shown in FIG. 8, known as the “optional dielectric layer structure.”

The mass loading effect is linked to the increase in mass per unit volume of the location where the wave propagates.

The wave can be considered to be all the more sensitive to the properties of the medium, as this coincides with the location of its maximum energy density.

Thus, the heavier the metal layer is comparatively (e.g., 10.22 g·cm⁻³ for a molybdenum metal layer vs. 2.65 g·cm⁻³ for a silica dielectric layer) and the closer it is to the piezoelectric layer where the wave's energy maximum is located, the more the phase velocity will be slowed down by the aforementioned mass loading effect.

Removing this high-density metal layer from the piezoelectric layer by the presence of a lower-density dielectric layer actually results in an increase in the phase velocity.

In the case of an optional dielectric layer, the mass loading effect is naturally taken into account of the two dielectric layers (e.g., silica) always present in the stack with a constant sum of thicknesses from one calculation to the next, with only the position of the metal layer changing, and therefore its influence on the phase velocity in the same way.

For elements common to FIGS. 2A and 2B and 8, please refer to the previous descriptions.

### Model 6

With regard to this optional dielectric layer structure shown in FIG. 8, a sixth series of models was used to evaluate the effect of the thicknesses of the dielectric layer 230 interposed between the piezoelectric layer 240 and the metal layer 220, and of the optional dielectric layer 330 interposed between the substrate 210 and the metal layer 220, on the characteristics of the interdigital SAW transducer 200.

For this evaluation, structures similar to the one shown in FIG. 8 were considered, corresponding to the metal layer structure of series 1 of models, except that this time the metal layer is made of molybdenum, the optional dielectric layer 330 is present, and the dielectric layer 230 and the optional dielectric layer 330 are each made of a layer of silicon oxide SiO₂ whose thickness has been varied.

For the calculations, a quality factor Q of 10,000 was considered for the LiTaO₃ layer and silicon substrate, 1,000 for SiO2, and 100 for molybdenum.

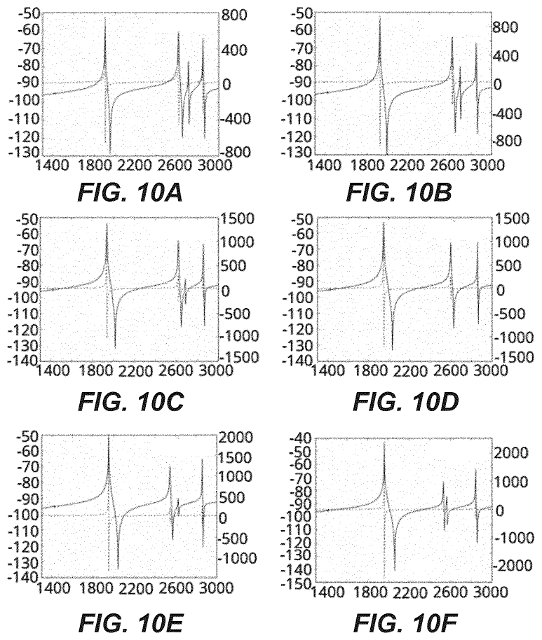

FIGS. 10A-10F are six graphs showing the evolution of harmonic admittance (Gₕₐᵣₘₒ conductance in solid lines expressed in dB/S·μm⁻¹ on the ordinate axes on the left-hand side of each graph, and Bₕₐᵣₘₒ susceptance in dashed lines expressed in S·m⁻¹ on the ordinate axes on the right-hand side of each graph), for SiO₂ thicknesses of 0, 20, 50, 100, 200 and 500 nm for the dielectric layer 230 and SiO₂ thicknesses of 520, 500, 470, 420, 320 and 20 nm for optional dielectric layer 330, respectively on the graphs of FIGS. 10A-10F.

As shown therein, the combined effect of the two dielectric layers 230 and 330 gives results similar to those of a single oxide layer, with the possibility of containing the thicknesses of these two layers.

For example, it may be advantageous to interpose a dielectric layer 230 and an optional dielectric layer 330, each with a thickness of less than 300 nm, preferably less than 100 nm.

It is also possible to interpose these dielectric layers 230 and 330 in such a way that the sum of their respective thicknesses remains below 600 nm.

Additionally, one of the parasitic responses has disappeared, corresponding to a second mode at around 2.7 GHz in the structure shown in the graph of FIG. 10D.

Thus, to eliminate this second mode, it is advantageous to choose oxide layer thicknesses such that the ratio of the optional dielectric layer thickness to the sum of the dielectric layer thickness and the optional dielectric layer thickness can be between 15% and 30%.

### Surface Acoustic Wave Devices and Filters

An application of the surface wave device according to the present disclosure is a filtering device comprising a pair of transducers such as the one shown in FIGS. 2A and 2B.

The skilled person is able to combine such resonators to obtain filtering functions.

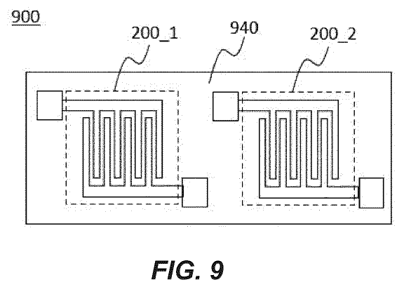

FIG. 9 is a non-limiting depiction of a quadrupole device 900 incorporating two interdigital SAW transducers 200_1 and 200_2, such as the one shown in FIGS. 2A and 2B or FIG. 8, in contact with the same piezoelectric layer 940 supported by a common substrate.

As explained above, one of the two SAW transducers is an input SAW transducer and the other is an output SAW transducer.

### Manufacturing Method

The devices shown in FIGS. 2A and 2B and 8 can be manufactured using methods that each include one or more direct bonding steps, in particular, molecular bonding, between two of the layers making up the device structures.

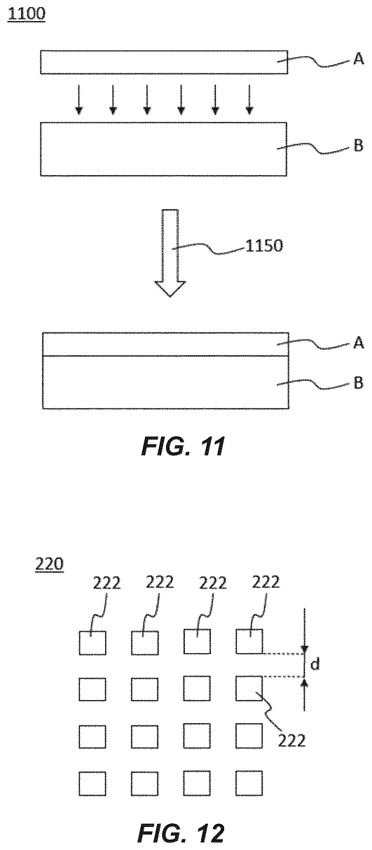

Thus, FIG. 11 shows a method 1100 for manufacturing any of the devices shown in FIGS. 2A and 2B and 8 by direct bonding 1150 of two elements A and B, where A can be the dielectric layer 230 and B the metal layer 220, A the piezoelectric layer 240 and B the dielectric layer 230, A the metal layer 220 and B the substrate 210, A the metal layer 220 and B the optional dielectric layer 330, A the optional dielectric layer 330 and B the substrate 210.

Each of elements A and B may be an individual element, or already bonded to other layers, for example, a first assembly comprising the piezoelectric layer 240 and the dielectric layer 230, the latter representing element A, may be bonded to a second assembly comprising the substrate 210 and the metal layer 220, the latter representing element B.

Of course, the present disclosure is not limited to the disclosure herein before and it is possible to add variants without departing from the scope of the invention as defined by the claims.

1. A surface acoustic wave device, comprising:
a substrate;
a piezoelectric layer above an upper face of the substrate;
a pair of electrodes in contact with the piezoelectric layer, the two electrodes comprising fingers extending in the same direction so as to form a periodic structure in which the fingers of the two electrodes alternate with one another, and having an interdigital distance separating the centers of two adjacent fingers of the same electrode;
a metal layer interposed between the substrate and the piezoelectric layer; and
at least one dielectric layer interposed between the metal layer and the piezoelectric layer,
wherein:
the metal layer has a thickness of between 5 nm and 100 nm; and
the at least one dielectric layer has a thickness of between 25 nm and 600 nm.

2. The surface acoustic wave device of claim 1, wherein the metal layer has a thickness of between 0.25% and 5% of the interdigital distance.

3. The surface acoustic wave device of claim 1, wherein the dielectric layer has a thickness of between 250 nm and 400 nm.

4. The surface acoustic wave device of claim 1, wherein the dielectric layer has a thickness greater than five times the thickness of the metal layer.

5. The surface acoustic wave device of claim 1, wherein the dielectric layer has a thickness of less than 200 nm.

6. The surface acoustic wave device of claim 1, further comprising a dielectric layer interposed between the substrate and the metal layer.

7. The surface acoustic wave device of claim 6, wherein the dielectric layer and the optional dielectric layer each have a thickness of less than 300 nm.

8. The surface acoustic wave device of claim 6, wherein the sum of the thickness of the dielectric layer and the thickness of the dielectric layer is less than 200 nm.

9. The surface acoustic wave device of claim 6, wherein the ratio of the optional dielectric layer thickness to the sum of the dielectric layer thickness and the optional dielectric layer thickness is between 15% and 30%.

10. The surface acoustic wave device of claim 1, wherein the piezoelectric layer comprises a juxtaposition of a lithium tantalate LiTaO₃ layer and a lithium niobate LiNbO₃ layer.

11. The surface acoustic wave device of claim 1, wherein the metal layer comprises metalized surfaces separated by a distance less than or equal to the interdigital distance.

12. A surface acoustic wave filter device comprising the surface acoustic wave device according to claim 1.

13. A method of manufacturing a device according to claim 1, comprising a direct bonding step.

14. The surface acoustic wave device of claim 2, wherein the dielectric layer has a thickness of between 250 nm and 400 nm.

15. The surface acoustic wave device of claim 2, wherein the dielectric layer has a thickness greater than five times the thickness of the metal layer.

16. The surface acoustic wave device of claim 2, wherein the dielectric layer has a thickness of less than 200 nm.

17. The surface acoustic wave device of claim 6, wherein the piezoelectric layer comprises a juxtaposition of a lithium tantalate LiTaO₃ layer and a lithium niobate LiNbO₃ layer.

18. The surface acoustic wave device of claim 17, wherein the dielectric layer and the optional dielectric layer each have a thickness of less than 300 nm.

19. The surface acoustic wave device of claim 17, wherein the sum of the thickness of the dielectric layer and the thickness of the dielectric layer is less than 200 nm.

20. The surface acoustic wave device of claim 6, wherein the metal layer comprises metalized surfaces separated by a distance less than or equal to the interdigital distance.
